(19) United States
(12) Patent Application Publication
(10) Pub. No.: US 2026/0040883 A1
(43) Pub. Date: Feb. 5, 2026

(54) RETENTION DEVICE

(71) Applicant: Niterra Co., Ltd., Nagoya-shi, Aichi (JP)

(72) Inventors: Yasuaki KIMIKADO, Nagoya-shi (JP); Daisuke UEMATSU, Nagoya-shi (JP); Honami OHARA, Nagoya-shi (JP); Takumi SANARI, Nagoya-shi (JP)

(21) Appl. No.: 19/118,647

(22) PCT Filed: Nov. 7, 2023
(86) PCT No.: PCT/JP2023/040004

§ 371 Date: Apr. 4, 2025

(30) Foreign Application Priority Data
Mar. 27, 2023 (JP) 2023-049750

(51) Int. Cl. H01L 21/683; B25B 11/00

(52) U.S. Cl. CPC H01L 21/6833; B25B 11/005

(57) ABSTRACT

A retention substrate includes: a plate-shaped member having a first surface and a second surface and containing a ceramic material as a main component, the first surface for retaining an object, the second surface disposed opposite to the first surface; a gas channel formed in the plate-shaped member; and a gas-permeable porous body filling part of the gas channel and containing a ceramic material as a main component. The gas channel including a vertical channel section and a horizontal channel section. The vertical channel section having a gas outlet opening in the first surface and extending from the gas outlet toward the second surface. The horizontal channel section connected to the vertical channel section and extending parallel to the first surface. The porous body filling the vertical channel section and forming a space adjacent to the second surface and inside the horizontal channel section.

### TECHNICAL FIELD

The present invention relates to a retention device.

### BACKGROUND ART

One example of a retention device that retains a wafer (semiconductor wafer) during semiconductor manufacturing is an electrostatic chuck (see PTL 1). The electrostatic chuck includes a retention substrate (ceramic substrate) formed mainly of an insulating ceramic material (for example, alumina). The wafer is retained on a surface of the retention substrate by electrostatic attraction. The electrostatic attraction occurs when a voltage is applied to a chuck electrode provided in the retention substrate.

In this type of electrostatic chuck, heat conduction gas, such as helium gas, is supplied between the retention substrate and the wafer during a plasma process, such as plasma etching, to remove heat from the wafer. Therefore, the retention substrate of the electrostatic chuck has a gas channel formed therein to allow the heat conduction gas supplied from the outside to flow toward the wafer.

High-frequency electric power applied in the plasma process may cause an abnormal discharge (arcing) in the gas channel, and the abnormal discharge may damage the wafer on the retention substrate. To reduce the occurrence of such an abnormal discharge, a gas-permeable porous body made of an insulating ceramic material is placed in the gas channel.

### CITATION LIST

### Patent Literature

PTL 1: Japanese Patent No. 4959905

### PROBLEM TO BE SOLVED BY THE INVENTION

In a conventional retention device, the contact surface area between the gas (inert gas, such as heat conduction gas) supplied through the gas channel and the surface of the porous body is small, and therefore a large pressure loss occurs in the gas in the porous body. Therefore, the amount of gas that can pass through the porous body is small relative to the amount of gas supplied to the gas channel from the outside.

### SUMMARY OF INVENTION

An object of the present invention is to provide a retention device including a retention substrate having a gas channel filled with a highly gas-permeable porous body.

### SOLUTION TO PROBLEM

The above-described problem is solved by the following means:
<1> A retention device including a retention substrate including: a plate-shaped member having a first surface and a second surface and containing a ceramic material as a main component, the first surface retaining an object, the second surface being disposed opposite to the first surface; a gas channel formed in the plate-shaped member; and a gas-permeable porous body that fills part of the gas channel and that contains a ceramic material as a main component, wherein the gas channel includes a vertical channel section and a horizontal channel section, the vertical channel section having a gas outlet that opens in the first surface and extending from the gas outlet toward the second surface, the horizontal channel section being connected to the vertical channel section and extending parallel to the first surface, and wherein the porous body fills the vertical channel section such that a space is formed on a side of the porous body adjacent to the second surface and inside the horizontal channel section.
<2> The retention device according to <1>, wherein the porous body has a convex end face that is an end face adjacent to the second surface and facing the space, the convex end face bulging toward the second surface.
<3> The retention device according to <1>, wherein the porous body has a concave end face that is an end face adjacent to the second surface and facing the space, the concave end face being recessed toward the first surface.
<4> The retention device according to <1>, wherein the horizontal channel section includes a bottom surface facing the porous body, and wherein the porous body includes a body portion that fills the vertical channel section and a support portion that extends from the body portion to the bottom surface such that the space is formed on a side of the body portion adjacent to the second surface and such that the body portion is supported above the bottom surface.
<5> The retention device according to any one of <1> to <4>, wherein the porous body includes a wide portion that is disposed closer to the second surface than the gas outlet and that is larger than the gas outlet in a radial direction.
<6> The retention device according to any one of <1> to <5>, wherein the space is provided at one end of the horizontal channel section.

### ADVANTAGEOUS EFFECTS OF INVENTION

The present invention provides a retention device including a retention substrate having a gas channel filled with a highly gas-permeable porous body.

### BRIEF DESCRIPTION OF DRAWINGS

FIG. 1 is a schematic perspective view illustrating the appearance of a retention device according to the first embodiment.

FIG. 2 is a schematic sectional view illustrating the internal structure of the retention device according to the first embodiment.

FIG. 3 is an enlarged sectional view of a part of a substrate gas channel in the retention substrate.

FIG. 4 is a sectional view of FIG. 3 taken along line A-A.

FIG. 5A, FIG. 5B, FIG. 5C, FIG. 5D, and FIG. 5E are schematic diagrams illustrating a method for manufacturing the retention substrate.

FIG. 6 is an enlarged sectional view of a part of a substrate gas channel in a retention substrate according to a second embodiment.

FIG. 7 is an enlarged sectional view of a part of a substrate gas channel in a retention substrate according to a third embodiment.

FIG. 8 is an enlarged sectional view of a part of a substrate gas channel in a retention substrate according to a fourth embodiment.

FIG. 9 is an enlarged sectional view of a part of a substrate gas channel in a retention substrate according to a fifth embodiment.

### DESCRIPTION OF EMBODIMENTS

### First Embodiment

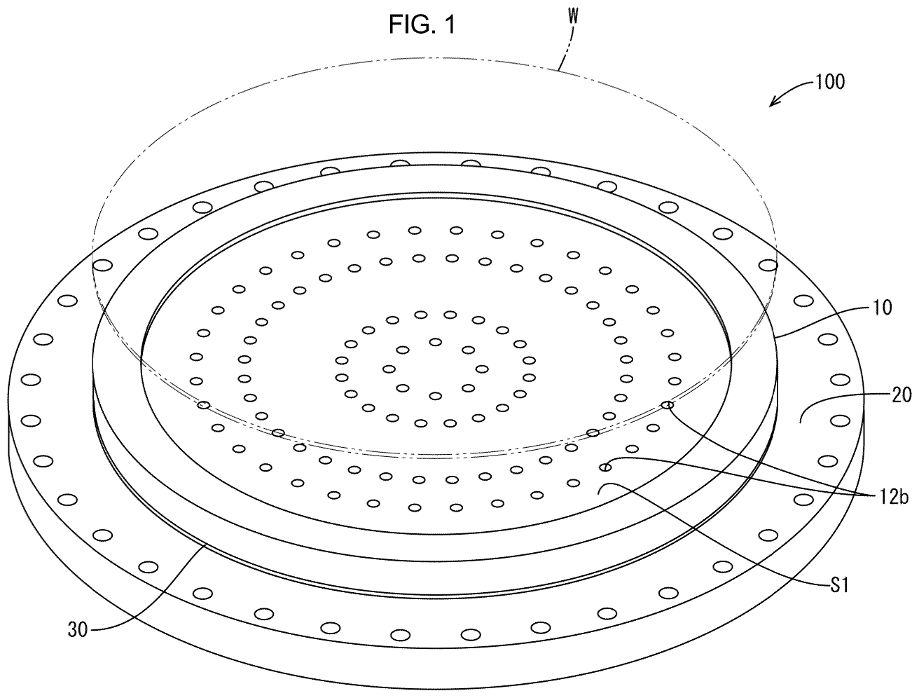

A retention device 100 according to a first embodiment will now be described with reference to FIGS. 1 to 6. The retention device 100 is an electrostatic chuck that retains an object (for example, a wafer W) by electrostatic attraction. The electrostatic chuck is used as a table on which the wafer W is placed, for example, in an etching process using plasma in a chamber with a reduced pressure.

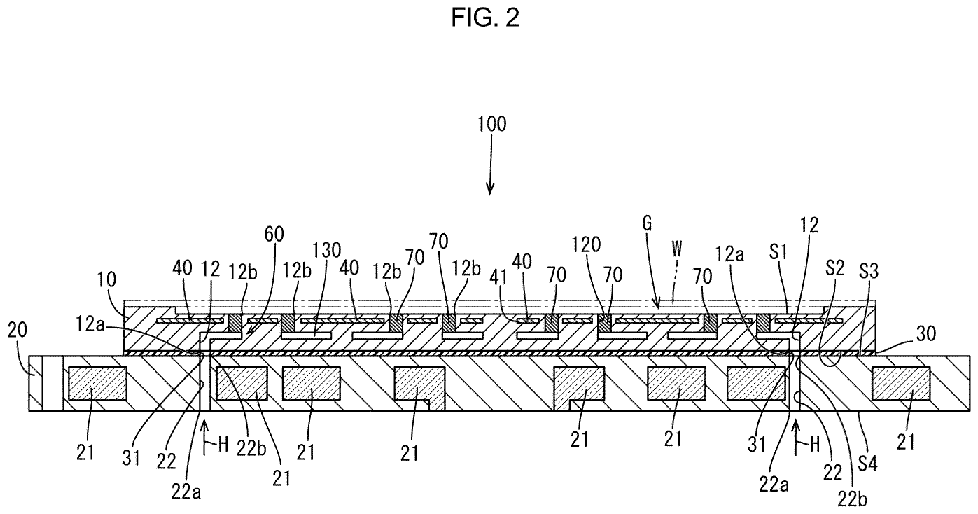

FIG. 1 is a schematic perspective view illustrating the appearance of the retention device 100 according to the first embodiment. FIG. 2 is a schematic sectional view illustrating the internal structure of the retention device 100 according to the first embodiment. The retention device 100 includes a disc-shaped retention substrate (ceramic substrate) 10 and a disc-shaped base member 20 larger than the retention substrate 10. For example, when the retention substrate 10 has the shape of a disc with a diameter of 300 mm and a thickness of 3 mm, the base member 20 has the shape of a disc with a diameter 340 mm and a thickness of 20 mm. The retention substrate 10 and the base member 20 may be provided with respective positioning portions (e.g., projections and recesses) for mutual positioning.

The retention substrate 10 and the base member 20 are stacked together in an up-down direction with the retention substrate 10 disposed above the base member 20. The retention substrate 10 and the base member 20 are joined together by a joining material 30 interposed therebetween.

The retention substrate 10 includes a substantially circular first surface S1 at an upper side and a substantially circular second surface S2 that is opposite to the first surface S1 (i.e., at a lower side) and that faces the base member 20. The base member 20 includes a substantially circular third surface S3 that is at an upper side and that faces the second surface S2 of the retention substrate 10 and a substantially circular fourth surface S4 that is opposite to the third surface S3 (i.e., at a lower side). The above-described joining material 30 spreads in the form of a layer between the second surface S2 of the retention substrate 10 and the third surface S3 of the base member 20.

The retention substrate 10 includes a plate-shaped member 11 that is disc-shaped and a substrate gas channel (example of a gas channel) 12 formed in the plate-shaped member 11. An upper surface of the plate-shaped member 11 is the first surface S1 of the retention substrate 10. A lower surface of the plate-shaped member 11 is the second surface S2 of the retention substrate 10.

The plate-shaped member 11 is a plate-shaped (disc-shaped) insulating member containing a ceramic material as a main component. In this specification, the term “main component” means a component with the highest content. The plate-shaped member 11 of the present embodiment is made of alumina (Al2O3). In other embodiments, the plate-shaped member 11 may be made of other ceramic materials, such as aluminum nitride (AlN).

The substrate gas channel (example of the gas channel) 12 constitutes a part of a channel 60 provided in the retention device 100 to allow passage of inert gas (for example, helium gas that serves as heat conduction gas). The substrate gas channel 12 is formed in the plate-shaped member 11 of the retention substrate 10. The substrate gas channel 12 is composed of a through hole extending through the retention substrate 10 and including inlets 12a opening in the second surface S2 of the retention substrate 10 and gas outlets 12b opening in the first surface S1. When inert gas is supplied through the inlets 12a, the inert gas passes through the substrate gas channel 12 and is finally discharged to the outside through the gas outlets 12b.

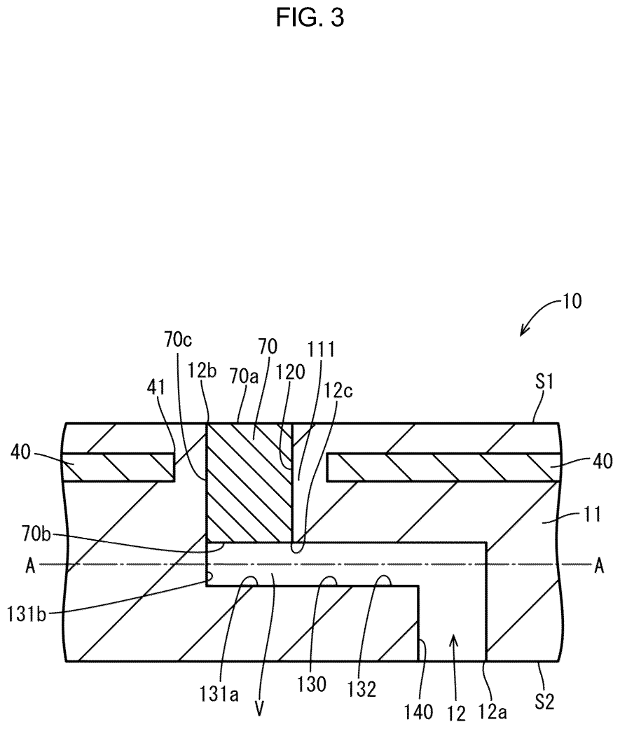

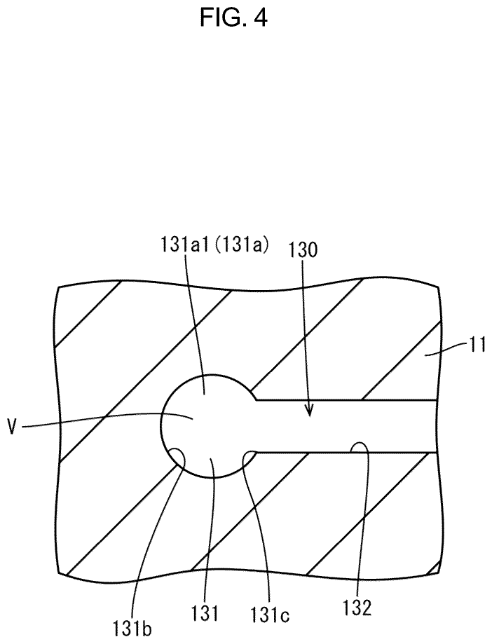

FIG. 3 is an enlarged sectional view of a part of the substrate gas channel 12 in the retention substrate 10. FIG. 4 is a sectional view of FIG. 3 taken along line A-A. FIG. 3 illustrates the cross-section of the retention substrate 10 taken along the thickness direction. As illustrated in FIG. 3 and other figures, the substrate gas channel 12 includes a first vertical channel section 120, a horizontal channel section 130, and a second vertical channel section 140.

The first vertical channel section 120 is a channel that has the gas outlet 12b opening in the first surface S1 and that extends from the gas outlet 12b toward the second surface S2 in the thickness direction of the plate-shaped member 11. The first vertical channel section 120 has a substantially cylindrical shape extending in the up-down direction, and has an opening 12c at an end opposite to the gas outlet 12b. The opening 12c is an inlet of the first vertical channel section 120 and has a diameter substantially equal to that of the gas outlet 12b. The first vertical channel section 120 is filled with a porous body 70 described below. The first vertical channel section 120 is a section of the substrate gas channel 12 between the gas outlet 12b and the opening 12c.

The horizontal channel section 130 is a channel that is connected to the first vertical channel section 120 and that extends parallel to the first surface S1. A downstream portion of the horizontal channel section 130 is connected to the opening 12c at the upstream side of the first vertical channel section 120. The inlet 12a is at the upstream side of the substrate gas channel 12, and the gas outlet 12b is at the downstream side.

The horizontal channel section 130 includes a bottom horizontal channel section 131 and a main horizontal channel section 132. The bottom horizontal channel section 131 includes a bottom portion 131a facing the porous body 70 that fills the first vertical channel section 120. The main horizontal channel section 132 connects the bottom horizontal channel section 131 to the second vertical channel section 140.

The bottom portion 131a of the bottom horizontal channel section 131 is substantially circular in plan view, and the size thereof is substantially equal to that of the gas outlet 12b and the opening 12c. A surface (bottom surface) 131a1 of the bottom portion 131a is flat. The bottom horizontal channel section 131 includes a substantially cylindrical peripheral wall 131b that extends upward toward the first surface S1 from the peripheral edge of the bottom portion 131a. The peripheral wall 131b has an opening 131c. This opening 131c is connected to a downstream portion of the main horizontal channel section 132. The bottom horizontal channel section 131 constitutes a flat channel that spreads parallel to the first surface S1.

The main horizontal channel section 132 constitutes an elongated channel extending parallel to the first surface S1 and having an upstream portion connected to the second vertical channel section 140 and a downstream portion connected to the opening 131c of the bottom horizontal channel section 131.

The second vertical channel section 140 is a channel that has the inlet 12a opening in the second surface S2 and that extends from the inlet 12a toward the first surface S1 in the thickness direction of the plate-shaped member 11. A downstream portion of the second vertical channel section 140 is connected to an upstream portion of the horizontal channel section 130. The inlet 12a serves as an inlet of the substrate gas channel 12. The second vertical channel section 140 has a substantially cylindrical shape extending in the up-down direction.

The retention substrate 10 also includes the porous body 70 that fills the first vertical channel section 120, which is part of the substrate gas channel 12. The porous body 70 is gas-permeable and contains a ceramic material as a main component. The porous body 70 will be described in detail below.

The retention substrate 10 also includes a chuck electrode 40, which is an electrode member. The chuck electrode 40 overall has a flat shape (layer shape) that is substantially parallel to the first surface S1. The chuck electrode 40 is made of a conductive material, such as tungsten, molybdenum, or platinum. As illustrated in FIG. 2, the chuck electrode 40 is disposed near the first surface S1 in the retention substrate 10 (plate-shaped member 11). The chuck electrode 40 is connected to an external power source through a terminal or the like. When electricity is supplied to the chuck electrode 40, electrostatic attraction occurs, and the wafer W is retained on the first surface S1 of the retention substrate 10 by the electrostatic attraction. The chuck electrode 40 has through holes 41 that extend therethrough in the thickness direction (up-down direction). In other embodiments, a high-frequency electrode or a heater electrode may be provided as the electrode member.

As illustrated in FIGS. 1 and 2, the first surface S1 of the retention substrate 10 has multiple gas outlets 12b. An outer peripheral edge portion of the first surface S1 has an annular shape and slightly projects upward from a portion inside the outer peripheral edge portion. Therefore, when the wafer W is retained on the first surface S1, as illustrated in FIG. 2, a clearance (gap) G is formed between the wafer W and the inner portion of the first surface S1.

The base member 20 contains, for example, a metal (e.g., aluminum or aluminum alloy), a metal-ceramic composite (Al—SiC), or a ceramic material (SiC) as a main component.

The base member 20 has a refrigerant channel 21 provided therein. Refrigerant (e.g., fluorinated inert liquid or water) is caused to flow through the refrigerant channel 21 to cool the plasma heat. When the refrigerant flows through the refrigerant channel 21, the base member 20 is cooled, and the retention substrate 10 is also cooled by heat transfer (heat conduction) between the base member 20 and the retention substrate 10 through the joining material 30. As a result, the wafer W retained on the first surface S1 of the retention substrate 10 is cooled. The temperature of the wafer W retained on the first surface S1 can be controlled by appropriately adjusting the flow rate of the refrigerant that flows through the refrigerant channel 21.

Base gas channels 22, which constitute parts of the channel 60, are provided in the base member 20. Each base gas channel 22 overall has the shape of a through hole extending through the base member 20 in the thickness direction, and has an inlet 22a opening in the fourth surface S4 of the base member 20 and an outlet 22b opening in the third surface S3. The inlets 22a serve as inlets of the base gas channels 22, and also serve as inlets of the entire channel 60 provided in the retention device 100.

The joining material 30 is formed of, for example, a bonding sheet containing a silicone-based organic joining material, an inorganic joining material, or an Al-based metal adhesive. The joining material 30 is preferably highly adhesive to both the retention substrate 10 and the base member 20, highly resistant to pressure, and highly thermally conductive.

The joining material 30 also has joining gas channels 31, which constitute parts of the channel 60, formed therein. The joining gas channels 31 are holes that extend through the layer-shaped joining material 30 in the thickness direction.

The channel 60 supplies inert gas (e.g., helium gas) to a side of the retention device 100 adjacent to the first surface S1. As described above, the first surface S1 has multiple gas outlets 12b, which are outlets of the channel 60. The inert gas is supplied to the side adjacent to the first surface S1 by being discharged from each gas outlet 12b. As described above, the channel 60 includes the base gas channels 22, the joining gas channels 31, and the substrate gas channel (gas channel) 12.

Multiple inlets 22a of the channel 60 are formed in the fourth surface S4 of the base member 20. When the inert gas (arrows H in FIG. 2) is supplied through the inlets 22a, the inert gas successively flows through the base gas channels 22, the joining gas channels 31, and the substrate gas channel (gas channel) 12 connected to the inlets 22a, and is finally discharged through the gas outlets 12b formed in the first surface S1.

The outlets 22b of the base gas channels 22 are connected to lower openings of the joining gas channels 31 (openings adjacent to the base member 20). Upper openings of the joining gas channels 31 (openings adjacent to the retention substrate 10) are connected to the inlets 12a of the substrate gas channel (gas channel) 12. Multiple inlets 12a of the substrate gas channel (gas channel) 12 are provided in the second surface S2 of the retention substrate 10.

The second vertical channel sections 140 including the inlets 12a of the substrate gas channel (gas channel) 12 are connected to multiple horizontal channel sections 130 at the downstream side thereof. Each of the horizontal channel sections 130 is connected to the corresponding first vertical channel section 120. Thus, the substrate gas channel (gas channel) 12 is shaped to branch into multiple paths from the upstream side to the downstream side thereof in the retention substrate 10 (plate-shaped member 11).

The porous body 70 and the substrate gas channel 12 filled with the porous body 70 will now be described in detail.

The porous body 70 is a gas-permeable member containing an insulating ceramic material as a main component and having many pores. Each of the first vertical channel sections 120 of the substrate gas channel 12 is filled with the porous body 70. The porous body 70 overall has a cylindrical shape extending in the up-down direction (thickness direction of the retention substrate 10), and has a mesh-shaped gas passage formed therein to allow inert gas to pass therethrough. The gas passage is composed of many pores connected to each other in the porous body 70. The pores are formed as marks left after particles of a pore-forming material are burnt (removed) during manufacture (firing) of the porous body 70. The pore-forming material may be, for example, synthetic resin beads or carbon powder.

The porous body 70 fills the first vertical channel section 120 such that a space V is formed therebelow. The porous body 70 fills the cylindrical first vertical channel section 120 such that a circular upper end face 70a is exposed at the gas outlet 12b and a circular lower end face 70b is exposed to the space V at the opening 12c. The space V is formed in the bottom horizontal channel section 131 of the horizontal channel section 130. In other words, the horizontal channel section 130 includes the space V in the bottom horizontal channel section 131 at the downstream end thereof. The space V is surrounded by the lower end face 70b of the porous body 70, the surface (bottom surface) 131a1 of the bottom portion 131a, and the surface of the peripheral wall 131b. The porous body 70 fills the first vertical channel section 120 such that the space V is formed on a side of the porous body 70 adjacent to the second surface S2 (that is, adjacent to the lower end face 70b) and inside the bottom horizontal channel section 131 of the horizontal channel section 130. As illustrated in FIG. 3, the porous body 70 is closer to the second surface S2 than the gas outlet 12b and closer to the first surface S1 than the horizontal channel section 130. In the present embodiment, the first surface S1 and the upper end face 70a are flush with each other. The porous body 70 has a peripheral surface 70c having a cylindrical shape extending straight in the up-down direction. The porous body 70 and a peripheral wall 111 of the first vertical channel section 120 are joined together by sintering.

The lower end face 70b of the porous body 70 faces the space V in the horizontal channel section 130 (bottom horizontal channel section 131), and the inert gas supplied from the upstream side of the substrate gas channel (gas channel) 12 flows into the porous body 70 through the lower end face 70b. The lower end face 70b is porous, and this lower end face 70b serves as an inlet for the inert gas. The lower end face 70b of the porous body 70 has an area equivalent to that of the circular bottom portion 131a facing the lower end face 70b. The bottom portion 131a of the bottom horizontal channel section 131 is positioned to overlap the lower end face 70b (upper end face 70b) of the porous body 70 in plan view. As illustrated in FIG. 4, in plan view, the bottom portion 131a of the bottom horizontal channel section 131 has a dimension larger than the width of the main horizontal channel section 132 of the horizontal channel section 130.

The above-described lower end face 70b comes into contact with the inert gas supplied from the upstream side through the substrate gas channel (gas channel) 12 over a large area (area exposed to the space V). Therefore, compared to the structure of the related art in which no space is provided below the porous body and in which the horizontal channel section is connected to a portion of the peripheral surface of the porous body, the retention device 100 of the present embodiment causes less pressure loss in the gas in the porous body 70.

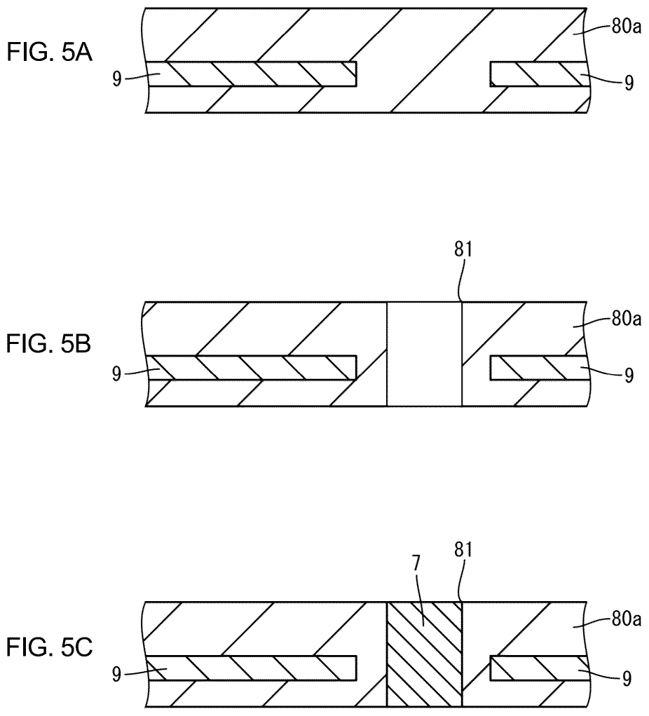

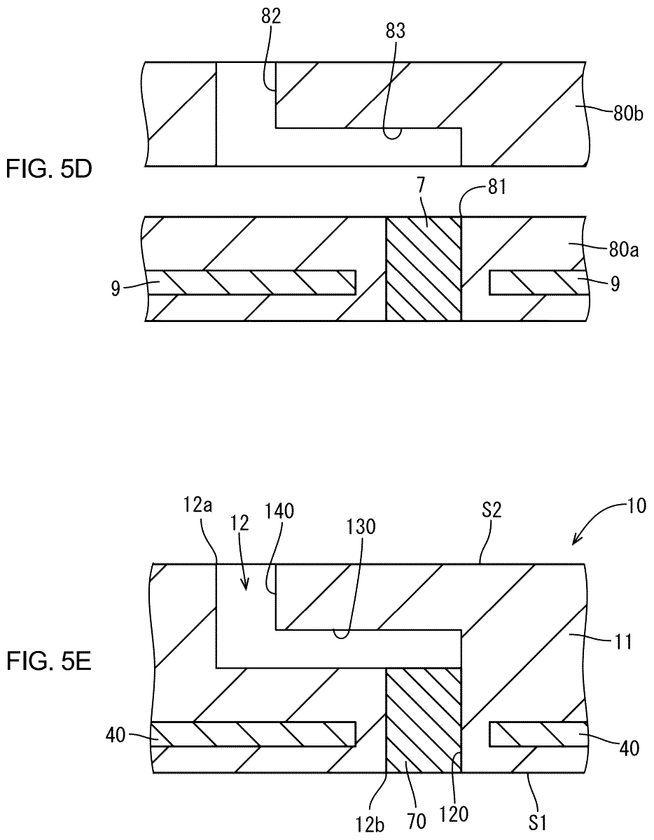

An example of a method for manufacturing the retention device 100 of the present embodiment will now be described. A method for manufacturing the retention substrate 10 included in the retention device 100 will be described first with reference to FIGS. 5 and 6. FIGS. 5 and 6 are schematic diagrams illustrating the method for manufacturing the retention substrate 10. In this method for manufacturing the retention substrate 10, sheet lamination using green sheets (ceramic green sheets) is applied. In FIGS. 5 and 6, the lower side (side adjacent to the second surface S2) of the retention substrate 10 is at the top of each figure, and the upper side (side adjacent to the first surface S1) of the retention substrate 10 is at the bottom of each figure.

First, as illustrated in FIG. 5A, a plurality of green sheets used to form the plate-shaped member 11 of the retention substrate 10 are stacked together to form a first multilayer body 80a. The green sheets that form the first multilayer body 80a include a predetermined green sheet on which a conductive layer 9 is formed, and the predetermined green sheet is stacked together with other green sheets.

Slurry used to form the green sheets is obtained by, for example, mixing a mixture including alumina powder, an acrylic binder, a dispersant, and a plasticizer together with an organic solvent by using a ball mill. The green sheets are formed by shaping the slurry into sheets by using a casting device and then drying the shaped sheets.

Metalizing paste used to form the conductive layer 9 is obtained by, for example, kneading a mixture including alumina powder, an acrylic binder, and an organic solvent together with conductive powder of tungsten, molybdenum, or the like. The conductive layer 9 is formed on the predetermined green sheet by printing the metalizing paste using, for example, a screen printer.

Next, as illustrated in FIG. 5B, a hole 81 that forms the first vertical channel section 120 is formed in the first multilayer body 80a at a predetermined position. The hole 81 is formed in a cylindrical shape that extends through the first multilayer body 80a in the thickness direction. The hole 81 is formed in the first multilayer body 80a at the predetermined position by using a known machining device (e.g., router).

Next, as illustrated in FIG. 5C, the hole 81 in the first multilayer body 80a is filled with porous body paste 7 used to form the porous body 70. The porous body paste 7 is obtained by, for example, kneading a mixture including alumina powder, a pore-forming material, a binder, and an organic solvent. The hole 81 may be filled with the porous body paste 7 by, for example, using an injection molding machine or a screen printer. The first multilayer body 80a is dried as appropriate after the hole 81 is filled with the porous body paste 7.

Subsequently, as illustrated in FIG. 5D, the first multilayer body 80a and a second multilayer body 80b are stacked together. The second multilayer body 80b is composed of a plurality of green sheets that are stacked together. The second multilayer body 80b has a hole 82 that forms the second vertical channel section 140 and a groove 83 that forms the horizontal channel section 130 at a predetermined position. The multilayer body including the first multilayer body 80a and the second multilayer body 80b is composed of, for example, 20 green sheets, which are bonded together by thermal compression bonding. The outer periphery of the multilayer body may be cut as appropriate. Then, the multilayer body is cut to produce a shaped body having the shape of a disc by machining. Subsequently, the obtained shaped body is subjected to degreasing and firing, and then the shaped body that has undergone degreasing and firing is subjected to firing (regular firing) to form a fired body.

Subsequently, a mask is placed on a surface of the fired body to cover a portion corresponding to the outer peripheral edge portion having a projecting shape, and, for example, shot blasting is performed in which ceramic particles or the like are propelled. Thus, the outer peripheral edge portion having a projecting shape is formed on the surface of the fired body. Subsequently, the surface of the fired body is subjected to polishing, for example, to obtain the retention substrate 10 including the plate-shaped member 11 as illustrated in FIG. 5E.

The above-described degreasing, firing, and regular firing are performed while the multilayer body including the first multilayer body 80a and the second multilayer body 80b is positioned such that the first surface S1 of the retention substrate 10 faces upward and the second surface S2 faces downward. During degreasing, firing, and regular firing, the porous body paste 7 (unfired composite) that fills the hole 81 and the multilayer body including the green sheets used to form the plate-shaped member 11, for example, are fired simultaneously.

The method for manufacturing the base member 20 is basically the same as the method for manufacturing the structure of the related art, and detailed description thereof will thus be omitted.

After the retention substrate 10 and the base member 20 are produced, the retention substrate 10 and the base member 20 are joined together by using the joining material 30. The manner in which the retention substrate 10 and the base member 20 are joined using the joining material 30 is basically the same as that in the structure of the related art, and detailed description thereof will thus be omitted. Thus, the retention device 100 is manufactured.

As described above, in the retention device 100 of the present embodiment, the space V is formed in the horizontal channel section 130 on the lower end face 70b of the porous body 70 that fills the first vertical channel section (example of a vertical channel section) 120 of the substrate gas channel (example of the gas channel) 12. The space V (clearance) is provided between the lower end face 70b of the porous body 70 and the bottom portion 131a of the bottom horizontal channel section 131 that faces the lower end face 70b, and the entirety of the lower end face 70b facing the space V functions as the inlet through which the inert gas flows into the porous body 70. The lower end face 70b comes into contact with the inert gas supplied from the upstream side over a large area, so that the pressure loss in the inert gas passing through the porous body 70 can be reduced, and gas permeability can be improved. The retention device 100 of the present embodiment includes the retention substrate 10 in which the substrate gas channel (example of the gas channel) 12 is filled with the porous body 70 having a high gas permeability as described above.

### Second Embodiment

A retention substrate 10A included in a retention device according to a second embodiment will now be described with reference to FIG. 6. FIG. 6 is an enlarged sectional view of a part of a substrate gas channel 12A in the retention substrate 10A according to the second embodiment. The basic structure of the retention substrate 10A of the present embodiment is the same as that in the first embodiment. Therefore, in FIG. 6, parts corresponding to those in the first embodiment are denoted by the same reference signs as those in the first embodiment with the character “A” attached, and detailed description thereof is omitted.

The retention substrate 10A includes a plate-shaped member 11A that is disc-shaped and a substrate gas channel 12A formed in the plate-shaped member 11A. An upper surface of the plate-shaped member 11A is a first surface SA1 of the retention substrate 10A, and a lower surface of the plate-shaped member 11A is a second surface SA2 of the retention substrate 10A. A chuck electrode 40A is provided in the retention substrate 10A.

Referring to FIG. 6, the substrate gas channel 12A includes a first vertical channel section 120A, a horizontal channel section 130A, and a second vertical channel section 140A. The first vertical channel section 120A, which is part of the substrate gas channel 12A, is filled with a gas-permeable porous body 70A containing a ceramic material as a main component.

The first vertical channel section 120A is a channel that has a gas outlet 12Ab opening in the first surface SA1 and that extends from the gas outlet 12Ab toward the second surface SA2 in the thickness direction of the plate-shaped member 11A. The first vertical channel section 120A has a substantially cylindrical shape extending in the up-down direction, and has an opening 12Ac at an end opposite to the gas outlet 12Ab. The opening 12Ac is an inlet of the first vertical channel section 120A and has a diameter substantially equal to that of the gas outlet 12Ab. The first vertical channel section 120A is a section of the substrate gas channel 12A between the gas outlet 12Ab and the opening 12Ac.

The horizontal channel section 130A is a channel that is connected to the first vertical channel section 120A and that extends parallel to the first surface SA1. A downstream portion of the horizontal channel section 130A is connected to the opening 12Ac at the upstream side of the first vertical channel section 120A.

The horizontal channel section 130A includes a bottom horizontal channel section 131A and a main horizontal channel section 132A. The bottom horizontal channel section 131A includes a bottom portion 131Aa facing the porous body 70A that fills the first vertical channel section 120A. The main horizontal channel section 132A connects the bottom horizontal channel section 131A to the second vertical channel section 140A.

The bottom portion 131Aa of the bottom horizontal channel section 131A is substantially circular in plan view, and the size thereof is substantially equal to that of the gas outlet 12Ab and the opening 12Ac. A surface (bottom surface) 131Aa1 of the bottom portion 131Aa is flat. The bottom horizontal channel section 131A includes a substantially cylindrical peripheral wall 131Ab that extends upward toward the first surface SA1 from the peripheral edge of the bottom portion 131Aa. The peripheral wall 131Ab has an opening 131Ac. This opening 131Ac is connected to a downstream portion of the main horizontal channel section 132A. The bottom horizontal channel section 131A constitutes a flat channel that spreads parallel to the first surface SA1.

The main horizontal channel section 132A constitutes an elongated channel extending parallel to the first surface SA1 and having an upstream portion connected to the second vertical channel section 140A and a downstream portion connected to the opening 131Ac of the bottom horizontal channel section 131A.

The second vertical channel section 140A is a channel that has an inlet 12Aa opening in the second surface SA2 and that extends from the inlet 12Aa toward the first surface SA1 in the thickness direction of the plate-shaped member 11A. A downstream portion of the second vertical channel section 140A is connected to an upstream portion of the horizontal channel section 130A.

The porous body 70A fills the first vertical channel section 120A such that a space VA is formed therebelow. The porous body 70A has an upper end face 70Aa that is flat and circular in plan view. The upper end face 70Aa is exposed at the gas outlet 12Ab. In the present embodiment, the first surface SA1 and the upper end face 70Aa are flush with each other.

In contrast, a lower end face of the porous body 70A is a convex end face 70Ab that bulges toward the second surface SA2. The convex end face 70Ab is a second-surface-side end face (lower end face) of the porous body 70A facing the space VA. The convex end face 70Ab is substantially circular in plan view, and gradually bulges toward the second surface SA2 from the peripheral edge toward the center.

The porous body 70A fills the cylindrical first vertical channel section 120A such that the convex end face 70Ab is exposed to the space VA at the opening 12Ac and protrudes into the bottom horizontal channel section 131A. The space VA is surrounded by the convex end face 70Ab, which is the lower end face of the porous body 70A, the surface (bottom surface) 131Aa1 of the bottom portion 131Aa, and the surface of the peripheral wall 131Ab. The horizontal channel section 130A includes the space VA in the bottom horizontal channel section 131A at the downstream end thereof. The bottom portion 131Aa of the bottom horizontal channel section 131A is positioned to overlap the convex end face 70Ab (upper end face 70Ab) of the porous body 70A in plan view.

The porous body 70A fills the first vertical channel section 120A such that the space VA is formed on a side of the porous body 70A adjacent to the second surface SA2 (that is, adjacent to the convex end face 70Ab) and inside the bottom horizontal channel section 131A of the horizontal channel section 130A.

The porous body 70A has a peripheral surface 70Ac having a cylindrical shape extending straight in the up-down direction. The porous body 70A and a peripheral wall 111A of the first vertical channel section 120A are joined together by sintering.

The convex end face 70Ab, which is the lower end face of the porous body 70A, faces the space VA in the horizontal channel section 130A (bottom horizontal channel section 131A), and the inert gas supplied from the upstream side of the substrate gas channel (gas channel) 12A flows into the porous body 70A through the convex end face 70Ab. The convex end face 70Ab is porous, and has a surface area larger than that of a flat end face.

In the above-described retention device of the present embodiment, the porous body 70A that fills the first vertical channel section (example of the vertical channel section) 120A of the substrate gas channel (example of the gas channel) 12A has the convex end face (lower end face) 70Ab as the end face thereof adjacent to the second surface

SA2. The convex end face 70Ab is shaped to protrude into the bottom horizontal channel section 131A, which is a portion of the horizontal channel section 130A. The space VA (clearance) is provided between the convex end face (lower end face) 70Ab and the bottom portion 131Aa of the bottom horizontal channel section 131A that faces the convex end face 70Ab, and the entirety of the convex end face 70Ab facing the space VA functions as the inlet through which the inert gas flows into the porous body 70A. The convex end face 70Ab comes into contact with the inert gas supplied from the upstream side over a particularly large area, so that the pressure loss in the inert gas passing through the porous body 70A can be reduced, and gas permeability can be improved.

As described above, the retention device of the present embodiment includes the retention substrate 10A in which the substrate gas channel 12A is filled with the porous body 70A having a high gas permeability.

### Third Embodiment

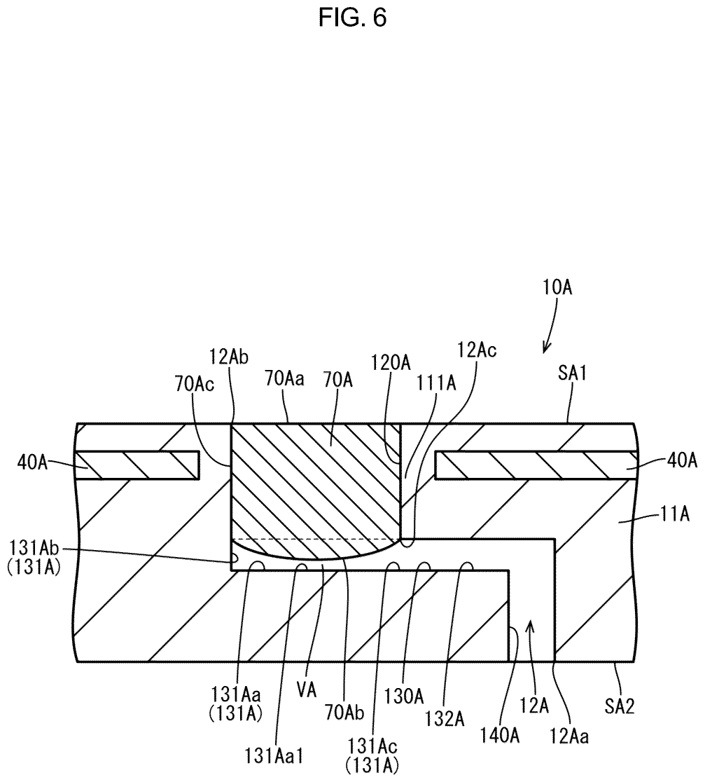

A retention substrate 10B included in a retention device according to a third embodiment will now be described with reference to FIG. 7. FIG. 7 is an enlarged sectional view of a part of a substrate gas channel 12B in the retention substrate 10B according to the third embodiment. The basic structure of the retention substrate 10B of the present embodiment is the same as that in the first embodiment. Therefore, in FIG. 7, parts corresponding to those in the first embodiment are denoted by the same reference signs as those in the first embodiment with the character “B” attached, and detailed description thereof is omitted.

The retention substrate 10B includes a plate-shaped member 11B that is disc-shaped and a substrate gas channel 12B formed in the plate-shaped member 11B. An upper surface of the plate-shaped member 11B is a first surface SB1 of the retention substrate 10B, and a lower surface of the plate-shaped member 11B is a second surface SB2 of the retention substrate 10B. A chuck electrode 40B is provided in the retention substrate 10B.

Referring to FIG. 7, the substrate gas channel 12B includes a first vertical channel section 120B, a horizontal channel section 130B, and a second vertical channel section 140B. The first vertical channel section 120B, which is part of the substrate gas channel 12B, is filled with a gas-permeable porous body 70B containing a ceramic material as a main component.

The first vertical channel section 120B is a channel that has a gas outlet 12Bb opening in the first surface SB1 and that extends from the gas outlet 12Bb toward the second surface SB2 in the thickness direction of the plate-shaped member 11B. The first vertical channel section 120B has a substantially cylindrical shape extending in the up-down direction, and has an opening 12Bc at an end opposite to the gas outlet 12Bb. The opening 12Bc is an inlet of the first vertical channel section 120B and has a diameter substantially equal to that of the gas outlet 12Bb. The first vertical channel section 120B is a section of the substrate gas channel 12B between the gas outlet 12Bb and the opening 12Bc.

The horizontal channel section 130B is a channel that is connected to the first vertical channel section 120B and that extends parallel to the first surface SB1. A downstream portion of the horizontal channel section 130B is connected to the opening 12Bc at the upstream side of the first vertical channel section 120B.

The horizontal channel section 130B includes a bottom horizontal channel section 131B and a main horizontal channel section 132B. The bottom horizontal channel section 131B includes a bottom portion 131Ba facing the porous body 70B that fills the first vertical channel section 120B. The main horizontal channel section 132B connects the bottom horizontal channel section 131B to the second vertical channel section 140B.

The bottom portion 131Ba of the bottom horizontal channel section 131B is substantially circular in plan view, and the size thereof is substantially equal to that of the gas outlet 12Bb and the opening 12Bc. A surface (bottom surface) 131Ba1 of the bottom portion 131Ba is flat. The bottom horizontal channel section 131B includes a substantially cylindrical peripheral wall 131Bb that extends upward toward the first surface SB1 from the peripheral edge of the bottom portion 131Ba. The peripheral wall 131Bb has an opening 131Bc. This opening 131Bc is connected to a downstream portion of the main horizontal channel section 132B. The bottom horizontal channel section 131B constitutes a flat channel that spreads parallel to the first surface SB1.

The main horizontal channel section 132B constitutes an elongated channel extending parallel to the first surface SB1 and having an upstream portion connected to the second vertical channel section 140B and a downstream portion connected to the opening 131Bc of the bottom horizontal channel section 131B.

The second vertical channel section 140B is a channel that has an inlet 12Ba opening in the second surface SB2 and that extends from the inlet 12Ba toward the first surface SB1 in the thickness direction of the plate-shaped member 11B. A downstream portion of the second vertical channel section 140B is connected to an upstream portion of the horizontal channel section 130B.

The porous body 70B fills the first vertical channel section 120B such that a space VB is formed therebelow. The porous body 70B has an upper end face 70Ba that is flat and circular in plan view. The upper end face 70Ba is exposed at the gas outlet 12Bb. In the present embodiment, the first surface SB1 and the upper end face 70Ba are flush with each other.

In contrast, a lower end face of the porous body 70B is a concave end face 70Bb that is recessed toward the first surface SB1. The concave end face 70Bb is a second-surface-side end face (lower end face) of the porous body 70B facing the space VB. The concave end face 70Bb is substantially circular in plan view, and is gradually recessed toward the first surface SB1 from the peripheral edge toward the center.

The porous body 70B fills the cylindrical first vertical channel section 120B such that the concave end face 70Bb is exposed to the space VB at the opening 12Bc and recessed into the first vertical channel section 120B. The space VB is surrounded by the concave end face 70Bb, which is the lower end face of the porous body 70B, the surface (bottom surface) 131Ba1 of the bottom portion 131Ba, and the surface of the peripheral wall 131Bb. The horizontal channel section 130B includes the space VB in the bottom horizontal channel section 131B at the downstream end thereof. The bottom portion 131Ba of the bottom horizontal channel section 131B is positioned to overlap the concave end face 70Bb (upper end face 70Bb) of the porous body 70B in plan view.

The porous body 70B fills the first vertical channel section 120B such that the space VB is formed on a side of the porous body 70B adjacent to the second surface SB2 (that is, adjacent to the concave end face 70Bb) and inside the bottom horizontal channel section 131B of the horizontal channel section 130B.

The porous body 70B has a peripheral surface 70Bc having a cylindrical shape extending straight in the up-down direction. The porous body 70B and a peripheral wall 111B of the first vertical channel section 120B are joined together by sintering.

The concave end face 70Bb, which is the lower end face of the porous body 70B, faces the space VB in the horizontal channel section 130B (bottom horizontal channel section 131B), and the inert gas supplied from the upstream side of the substrate gas channel (gas channel) 12B flows into the porous body 70B through the concave end face 70Bb. The concave end face 70Bb is porous, and has a surface area larger than that of a flat end face. In addition, the thickness (length in the height direction) of the porous body 70B is smaller in a central region of the concave end face 70Bb in plan view than in a region around the central region.

In the above-described retention device of the present embodiment, the porous body 70B that fills the first vertical channel section (example of the vertical channel section) 120B of the substrate gas channel (example of the gas channel) 12B has the concave end face (lower end face) 70Bb as the end face thereof adjacent to the second surface SB2. The concave end face 70Bb is shaped to be recessed into the first vertical channel section 120B. The space VB (clearance) is provided between the concave end face (lower end face) 70Bb and the bottom portion 131Ba of the bottom horizontal channel section 131B that faces the concave end face 70Bb, and the entirety of the concave end face 70Bb facing the space VB functions as the inlet through which the inert gas flows into the porous body 70B. The concave end face 70Bb comes into contact with the inert gas supplied from the upstream side over a particularly large area, so that the pressure loss in the inert gas passing through the porous body 70B can be reduced. In addition, since the porous body 70B has a small thickness in the central region thereof as described above, gas permeability can be improved.

As described above, the retention device of the present embodiment includes the retention substrate 10B in which the substrate gas channel 12B is filled with the porous body 70B having a high gas permeability.

### Fourth Embodiment

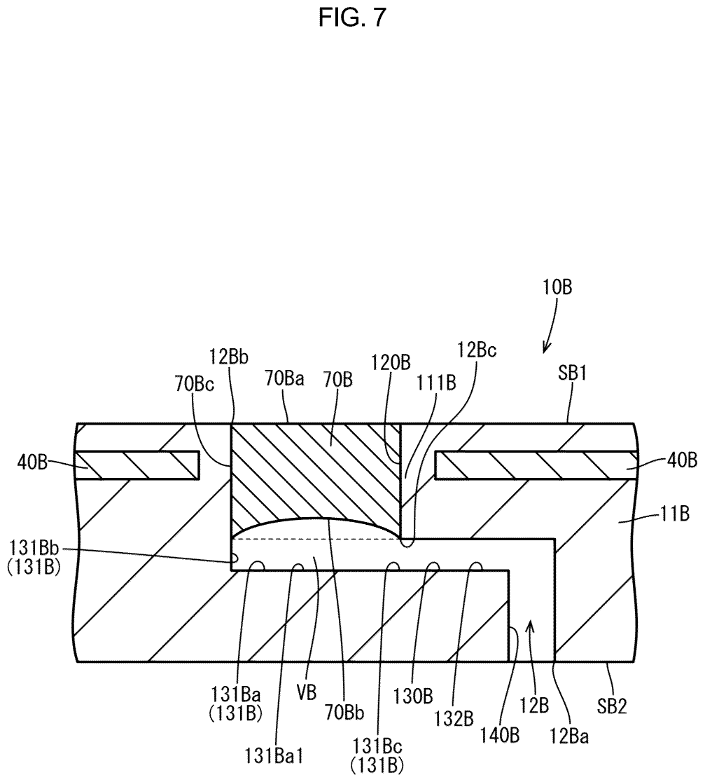

A retention substrate 10C included in a retention device according to a fourth embodiment will now be described with reference to FIG. 8. FIG. 8 is an enlarged sectional view of a part of a substrate gas channel 12C in the retention substrate 10C according to the fourth embodiment. The basic structure of the retention substrate 10C of the present embodiment is the same as that in the first embodiment. Therefore, in FIG. 8, parts corresponding to those in the first embodiment are denoted by the same reference signs as those in the first embodiment with the character “C” attached, and detailed description thereof is omitted.

The retention substrate 10C includes a plate-shaped member 11C that is disc-shaped and a substrate gas channel 12C formed in the plate-shaped member 11C. An upper surface of the plate-shaped member 11C is a first surface SC1 of the retention substrate 10C, and a lower surface of the plate-shaped member 11C is a second surface SC2 of the retention substrate 10C. A chuck electrode 40C is provided in the retention substrate 10C.

Referring to FIG. 8, the substrate gas channel 12C includes a first vertical channel section 120C, a horizontal channel section 130C, and a second vertical channel section 140C. The first vertical channel section 120C, which is part of the substrate gas channel 12C, is filled with a gas-permeable porous body 70C containing a ceramic material as a main component.

The first vertical channel section 120C is a channel that has a gas outlet 12Cb opening in the first surface SC1 and that extends from the gas outlet 12Cb toward the second surface SC2 in the thickness direction of the plate-shaped member 11C. The first vertical channel section 120C has a substantially cylindrical shape extending in the up-down direction, and has an opening 12Cc at an end opposite to the gas outlet 12Cb. The opening 12Cc is an inlet of the first vertical channel section 120C and has a diameter substantially equal to that of the gas outlet 12Cb. The first vertical channel section 120C is a section of the substrate gas channel 12C between the gas outlet 12Cb and the opening 12Cc.

The horizontal channel section 130C is a channel that is connected to the first vertical channel section 120C and that extends parallel to the first surface SC1. A downstream portion of the horizontal channel section 130C is connected to the opening 12Cc at the upstream side of the first vertical channel section 120C.

The horizontal channel section 130C includes a bottom horizontal channel section 131C and a main horizontal channel section 132C. The bottom horizontal channel section 131C includes a bottom portion 131Ca facing the porous body 70C that fills the first vertical channel section 120C. The main horizontal channel section 132C connects the bottom horizontal channel section 131C to the second vertical channel section 140C.

The bottom portion 131Ca of the bottom horizontal channel section 131C is substantially circular in plan view, and the size thereof is substantially equal to that of the gas outlet 12Cb and the opening 12Cc. A surface (bottom surface) 131Ca1 of the bottom portion 131Ca is flat. The bottom horizontal channel section 131C includes a substantially cylindrical peripheral wall 131Cb that extends upward toward the first surface SC1 from the peripheral edge of the bottom portion 131Ca. The peripheral wall 131Cb has an opening 131Cc. This opening 131Cc is connected to a downstream portion of the main horizontal channel section 132C. The bottom horizontal channel section 131C constitutes a flat channel that spreads parallel to the first surface SC1.

The main horizontal channel section 132C constitutes an elongated channel extending parallel to the first surface SC1 and having an upstream portion connected to the second vertical channel section 140C and a downstream portion connected to the opening 131Cc of the bottom horizontal channel section 131C.

The second vertical channel section 140C is a channel that has an inlet 12Ca opening in the second surface SC2 and that extends from the inlet 12Ca toward the first surface SC1 in the thickness direction of the plate-shaped member 11C. A downstream portion of the second vertical channel section 140C is connected to an upstream portion of the horizontal channel section 130C.

The porous body 70C fills the first vertical channel section 120C such that a space VC is formed therebelow. The porous body 70C includes a body portion 71C and a support portion 72C. The body portion 71C is substantially cylindrical and fills the first vertical channel section 120C. The support portion 72C extends from the body portion 71C to the bottom surface 131Ca1 such that the space VC is formed on a side of the body portion 71C adjacent to the second surface SC2 and such that the body portion 71C is supported above the bottom surface 131Ca1.

An upper end face 70Ca of the porous body 70C is a flat upper end face of the body portion 71C, and is circular in plan view. The upper end face 70Ca is exposed at the gas outlet 12Cb. In the present embodiment, the first surface SC1 and the upper end face 70Ca are flush with each other.

A lower end face 70Cb of the body portion 71C of the porous body 70C is mostly flat, and is at the height of the opening 12Cc. The lower end face 70Cb faces the bottom surface 131Ca1 of the bottom portion 131Ca with the space VC disposed therebetween. The above-described support portion 72C is provided at an edge of the lower end face 70Cb (at the end of the bottom horizontal channel section 131C opposite to the opening 131Cc). The support portion 72C is shaped to extend from the lower end face 70Cb of the body portion 71C to the bottom surface 131Ca1 of the bottom horizontal channel section 131C.

The porous body 70C fills the cylindrical first vertical channel section 120C such that a lower end portion of the porous body 70C including the lower end face 70Cb and the support portion 72Cb is exposed to the space VC at the opening 12Cc and such that the support portion 72Cb extends to the bottom surface 131Ca1 of the bottom horizontal channel section 131C. The space VC is surrounded by the lower end face 70Cb and the support portion 72Cb that constitute the lower end portion of the porous body 70C, the surface (bottom surface) 131Ca1 of the bottom portion 131Ca, and the surface of the peripheral wall 131Cb. The horizontal channel section 130C includes the space VC in the bottom horizontal channel section 131C at the downstream end thereof. The bottom portion 131Ca of the bottom horizontal channel section 131C is positioned to overlap the lower end portion (upper end face 70Bb) of the porous body 70B in plan view.

The porous body 70C fills the first vertical channel section 120C such that the space VC is formed on a side of the porous body 70C adjacent to the second surface SC2 (that is, adjacent to the lower end face 70Cb) and inside the bottom horizontal channel section 131C of the horizontal channel section 130C.

The porous body 70C has a peripheral surface 70Cc having a cylindrical shape extending substantially straight in the up-down direction. The body portion 71C of the porous body 70C and a peripheral wall 111C of the first vertical channel section 120C are joined together by sintering. In the present embodiment, a portion of the support portion 72Cb and a portion of the peripheral wall 131Cb are also joined together by sintering.

The lower end face 70Cb and the support portion 72Cb of the porous body 70C face the space VC in the horizontal channel section 130C (bottom horizontal channel section 131C), and the inert gas supplied from the upstream side of the substrate gas channel (gas channel) 12C flows into the porous body 70C through the lower end face 70Cb and the support portion 72Cb. The lower end face 70Cb and the support portion 72Cb are porous, and come into contact with the inert gas over a large area. The porous body 70C is supported on the bottom portion 131Ca (bottom surface 131Ca1) by the support portion 72Cb and is fixed to a portion of the peripheral wall 131Cb.

In the above-described retention device of the present embodiment, the porous body 70C that fills the first vertical channel section (example of the vertical channel section) 120C of the substrate gas channel (example of the gas channel) 12C has the lower end face 70Cb and the like at the side adjacent to the second surface SC2, and the space VC (clearance) is provided between the lower end face 70Cb and the bottom portion 131Ca of the bottom horizontal channel section 131C that faces the lower end face 70Cb. The entireties of the lower end face 70Cb and the support portion 72Cb facing the space VC function as the inlet through which the inert gas flows into the porous body 70C. The lower end face 70Cb and the like come into contact with the inert gas supplied from the upstream side over a large area, so that the pressure loss in the inert gas passing through the porous body 70C can be reduced. In addition, as described above, the lower end portion of the porous body 70C is supported on the bottom portion 131Ca (bottom surface 131Ca1) by the support portion 72Cb. Therefore, when the retention device (retention substrate 10C) is manufactured (during degreasing, firing, and regular firing), the porous body 70C can be prevented from, for example, falling into the space VC from the hole that forms the first vertical channel section 120C.

As described above, the retention device of the present embodiment includes the retention substrate 10C in which the substrate gas channel 12C is filled with the porous body 70C having a high gas permeability.

### Fifth Embodiment

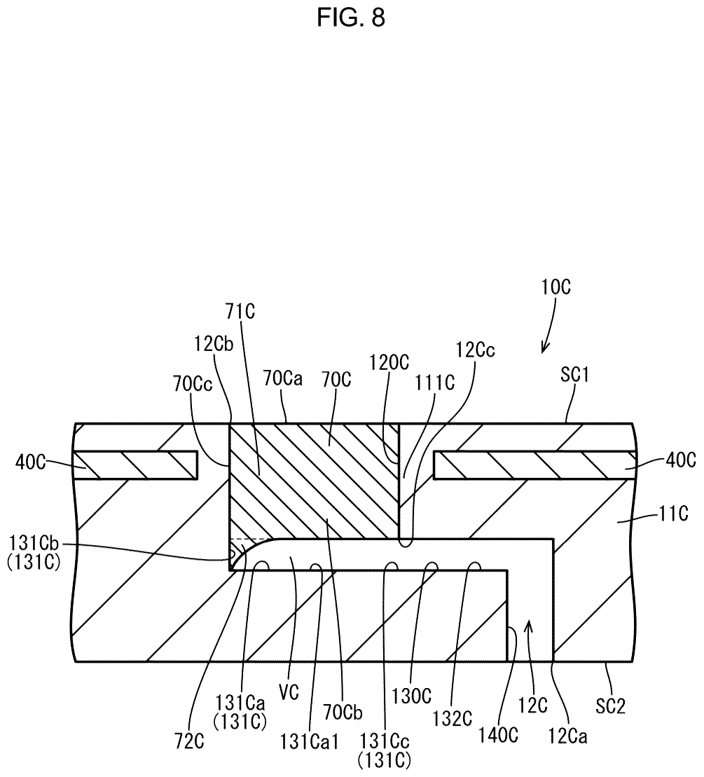

A retention substrate 10D included in a retention device according to a fifth embodiment will now be described with reference to FIG. 9. FIG. 9 is an enlarged sectional view of a part of a substrate gas channel 12D in the retention substrate 10D according to the fifth embodiment. The basic structure of the retention substrate 10D of the present embodiment is the same as that in the first embodiment. Therefore, in FIG. 9, parts corresponding to those in the first embodiment are denoted by the same reference signs as those in the first embodiment with the character “D” attached, and detailed description thereof is omitted.

The retention substrate 10D includes a plate-shaped member 11D that is disc-shaped and a substrate gas channel 12D formed in the plate-shaped member 11D. An upper surface of the plate-shaped member 11D is a first surface SD1 of the retention substrate 10D, and a lower surface of the plate-shaped member 11D is a second surface SD2 of the retention substrate 10D. A chuck electrode 40D is provided in the retention substrate 10D.

Referring to FIG. 9, the substrate gas channel 12D includes a first vertical channel section 120D, a horizontal channel section 130D, and a second vertical channel section 140D. The first vertical channel section 120D, which is part of the substrate gas channel 12D, is filled with a gas-permeable porous body 70D containing a ceramic material as a main component.

The first vertical channel section 120D is a channel that has a gas outlet 12Db opening in the first surface SD1 and that extends from the gas outlet 12Db toward the second surface SD2 in the thickness direction of the plate-shaped member 11D. The first vertical channel section 120D has a cylindrical shape including an upper portion having a small inner diameter and a lower portion having a large inner diameter, and an opening 12Dc is provided at an end opposite to the gas outlet 12Db. The opening 12Dc is an inlet of the first vertical channel section 120D and has an inner diameter greater than an inner diameter r of the gas outlet 12Db. The first vertical channel section 120D is a section of the substrate gas channel 12D between the gas outlet 12Db and the opening 12Dc.

The first vertical channel section 120D includes a small-diameter accommodating portion 121D and a wide accommodating portion 122D. The small-diameter accommodating portion 121D is disposed at the upper end (end adjacent to the first surface SD1) and has the gas outlet 12Db. The wide accommodating portion 122D is connected to a lower end (end adjacent to the second surface SD2) of the small-diameter accommodating portion 121D and has an inner diameter greater than that of the small-diameter accommodating portion 121D.

The small-diameter accommodating portion 121D is a cylindrical hole having a peripheral surface extending straight from the gas outlet 12Db toward the second surface SD2 in the thickness direction of the plate-shaped member 11D.

The wide accommodating portion 122D includes a wide tapered accommodating portion 123D connected to the lower end (end adjacent to the second surface SD2) of the small-diameter accommodating portion 121D and a wide large-diameter accommodating portion 124D connected to a lower end (end adjacent to the second surface SD2) of the wide tapered accommodating portion 123D.

The wide tapered accommodating portion 123D is a cylindrical hole having an annular tapered peripheral surface that is tapered to widen outward in the direction from the first surface SD1 to the second surface SD2. The wide large-diameter accommodating portion 124D is a cylindrical hole having a peripheral surface extending straight from the wide tapered accommodating portion 123D toward the second surface SD2 in the thickness direction of the plate-shaped member 11D and having an inner diameter greater than that of the small-diameter accommodating portion 121D.

The horizontal channel section 130D is a channel that is connected to the first vertical channel section 120D and that extends parallel to the first surface SD1. A downstream portion of the horizontal channel section 130D is connected to the opening 12Dc at the upstream side of the first vertical channel section 120D.

The horizontal channel section 130D includes a bottom horizontal channel section 131D and a main horizontal channel section 132D. The bottom horizontal channel section 131D includes a bottom portion 131Da facing the porous body 70D that fills the first vertical channel section 120D. The main horizontal channel section 132D connects the bottom horizontal channel section 131D to the second vertical channel section 140D.

The bottom portion 131Da of the bottom horizontal channel section 131D is substantially circular in plan view, and the size thereof is substantially equal to that of the opening 12Dc. A surface (bottom surface) 131Da1 of the bottom portion 131Da is flat. The bottom horizontal channel section 131D includes a substantially cylindrical peripheral wall 131Db that extends upward toward the first surface SD1 from the peripheral edge of the bottom portion 131Da. The peripheral wall 131Db has an opening 131Dc. This opening 131Dc is connected to a downstream portion of the main horizontal channel section 132D. The bottom horizontal channel section 131D constitutes a flat channel that spreads parallel to the first surface SD1.

The main horizontal channel section 132D constitutes an elongated channel extending parallel to the first surface SD1 and having an upstream portion connected to the second vertical channel section 140D and a downstream portion connected to the opening 131Dc of the bottom horizontal channel section 131D.

The second vertical channel section 140D is a channel that has an inlet 12Da opening in the second surface SD2 and that extends from the inlet 12Da toward the first surface SD1 in the thickness direction of the plate-shaped member 11D. A downstream portion of the second vertical channel section 140D is connected to an upstream portion of the horizontal channel section 130D.

The porous body 70D fills the first vertical channel section 120D such that a space VD is formed therebelow. The porous body 70D has an upper end face 70Da that is flat and circular in plan view. The upper end face 70Da is exposed at the gas outlet 12Db. In the present embodiment, the first surface SD1 and the upper end face 70Da are flush with each other.

A lower end face 70Db of the porous body 70D is an end face of the porous body 70D at a side adjacent to the second surface SD2 that faces the space VD, and has a substantially circular shape larger than the upper end face 70Da in plan view.

The porous body 70D includes an end portion 71D and a wide portion 72D disposed in the first vertical channel section 120D. The end portion 71D is cylindrical and fills a space adjacent to the first surface SD1. The wide portion 72D is substantially cylindrical and is connected to a lower end (end adjacent to the second surface SD2) of the end portion 71D.

The wide portion 72D is disposed closer to the second surface SD2 than the gas outlet 12Db and is larger than the gas outlet 12Db in the radial direction. The wide portion 72D includes a tapered portion 73D and a column-shaped portion 74D. The tapered portion 73D has an annular tapered surface 73Da tapered to widen in the direction from the first surface SD1 to the second surface SD2. The column-shaped portion 74D is cylindrical and extends straight from the tapered portion 73D toward the second surface S2. The lower end face 70Db of the column-shaped portion 74D is substantially at the height of the top of the horizontal channel section 130D.

The lower end face 70Db is exposed to the space VD at the opening 12Dc, and the inert gas flows into the porous body 70D through the lower end face 70Db. The opening 12Dc is disposed opposite to the gas outlet 12Db and closer to the first surface SD1 than the bottom horizontal channel section 130D, and opens toward the bottom portion 131Da such that the porous body 70D is exposed to face the bottom portion 131Da at the side adjacent to the second surface SD2. The lower end face 70Db (end face adjacent to the second surface SD2) of the porous body 70D (column-shaped portion 74D) exposed at the opening 12Dc faces the surface (bottom surface) 131Da1 of the bottom portion 131Da over the entire area thereof. In the present embodiment, the size of the surface (bottom surface) 131Da1 of the bottom portion 131Da is the same as that of the lower end face 70Db. The main horizontal channel section 132D extending parallel to the first surface SD1 is connected to the bottom horizontal channel section 130D including the bottom portion 131Da.

Since the lower end face 70Db of the porous body 70D faces the bottom portion 131Da of the bottom horizontal channel section 131D, which is not filled with the porous body 70D, over the entire area thereof as described above, the inert gas can flow into the porous body 70D at a sufficient flow rate.

The porous body 70D of the present embodiment is formed such that an angle θ between a peripheral surface 71Db of the end portion 71D connected to an end of the wide portion 72D (tapered portion 73D) adjacent to the first surface SD1 and the tapered surface 73Da of the tapered portion 73D is set to satisfy 90°<θ<180°. Assume that, when the retention substrate 10D is manufactured (e.g., during degreasing and firing), the porous body paste used to form the porous body 70D receives a force in a direction from the second surface SD2 to the first surface SD1 and is urged to move in the direction from the second surface SD2 to the first surface SD1 in the hole that forms the first vertical channel section 120D. Even in such a case, when the angle θ is set as described above, a portion of the porous body paste corresponding to the wide portion 72D of the porous body 70D is caught (restrained) by a portion corresponding to an annular corner portion 111Da (portion around the small-diameter accommodating portion 121D and around the wide tapered accommodating portion 123D) of a peripheral wall 111D of the first vertical channel section 120D disposed around the porous body 70D. Thus, the porous body 70D can be prevented from falling out of the first vertical channel section 120D due to, for example, deformation of the porous body paste in the hole that forms the first vertical channel section 120D. As a result, in the retention device of the present embodiment, the porous body 70D can be disposed at a predetermined position in the substrate gas channel 12D.

The upper end face 70Da of the porous body 70D is the upper end face of the end portion 71D, and the lower end face 70Db of the porous body 70D is the lower end face of the wide portion 72D (column-shaped portion 72D2). The lower end face 70Db of the porous body 70D is substantially at the height of the opening 12Dc.

The porous body 70D fills the first vertical channel section 120D such that the lower end face 70Db is exposed to the space VD at the opening 12Dc. The space VD is surrounded by the lower end face 70Db of the porous body 70D, the surface (bottom surface) 131Da1 of the bottom portion 131Da, and the surface of the peripheral wall 131Db. The horizontal channel section 130D includes the space VD in the bottom horizontal channel section 131D at the downstream end thereof. The bottom portion 131Da of the bottom horizontal channel section 131D is positioned to overlap the lower end face 70Db of the porous body 70D in plan view.

The porous body 70D fills the first vertical channel section 120D such that the space VD is formed on a side of the porous body 70D adjacent to the second surface SD2 (that is, adjacent to the lower end face 70Db) and inside the bottom horizontal channel section 131D of the horizontal channel section 130D. The peripheral surface of the porous body 70D and the peripheral wall 111D of the first vertical channel section 120D are joined together by sintering.

The lower end face 70Db of the porous body 70D faces the space VD in the horizontal channel section 130D (bottom horizontal channel section 131D), and the inert gas supplied from the upstream side of the substrate gas channel 12D flows into the porous body 70D through the lower end face 70Db. The lower end face 70Db comes into contact with the inert gas over a large area (area exposed to the space V).

In the above-described retention device of the present embodiment, the space VD (clearance) is provided between the lower end face 70Db of the porous body 70D that fills the first vertical channel section (example of the vertical channel section) 120D of the substrate gas channel (example of the gas channel) 12D and the bottom portion 131Da of the bottom horizontal channel section 131D that faces the lower end face 70Db. The entirety of the lower end face 70Db facing the space VD functions as the inlet through which the inert gas flows into the porous body 70D. The lower end face 70Db comes into contact with the inert gas supplied from the upstream side over a particularly large area, so that the pressure loss in the inert gas passing through the porous body 70D can be reduced, and gas permeability can be improved.

As described above, the retention device of the present embodiment includes the retention substrate 10D in which the substrate gas channel 12D is filled with the porous body 70D having a high gas permeability.

In the present embodiment, the porous body 70D includes the wide portion 72D having an outer diameter greater than the inner diameter r of the gas outlet 12Db at a side adjacent to the second surface SD2. Therefore, when the retention substrate 10D is manufactured (e.g., during degreasing and firing), even if the porous body paste used to form the porous body 70D receives a force in the direction from the second surface SD2 to the first surface SD1 and is urged to move in the direction from the second surface SD2 to the first surface SD1 in the hole that forms the first vertical channel section 120D, a portion of the porous body paste corresponding to the wide portion 72D, for example, of the porous body 70D is caught by a portion corresponding to the peripheral wall 111D of the first vertical channel section 120D disposed around the porous body 70D. Thus, the porous body 70D can be prevented from falling out of the first vertical channel section 120D due to, for example, deformation of the porous body paste in the hole that forms the first vertical channel section 120D.

In particular, the porous body 70D of the present embodiment includes the end portion 71D, the tapered portion 73D, and the wide portion 74D connected in that order in the direction from the first surface SDI to the second surface SD2. The end portion 71D is cylindrical, and the lower end thereof is connected to the tapered portion 73D that is wider than the end portion 71D. The tapered portion 73D has the tapered surface 73Da tapered to widen in the direction from the first surface SD1 to the second surface SD2. The column-shaped portion 74D has a cylindrical shape that extends straight from the tapered surface 73Da (tapered portion 73D) toward the second surface SD2. Thus, in the porous body 70D of the present embodiment, the tapered portion 73D including the tapered surface 73Da is disposed between the straight cylindrical end portion 71D and the straight cylindrical column-shaped portion 74D in the thickness direction of the plate-shaped member 11D.

When the porous body 70D has the above-described structure, the porous body 70D is not easily displaced, and the adhesion between the porous body 70D and the plate-shaped member 11D (peripheral wall 111D) surrounding the porous body 70D can be increased. During manufacture of the retention substrate 10D, the multilayer body composed of green sheets used to form the plate-shaped member 11D (shaped body) is fired. The multilayer body has a hole that forms the first vertical channel section 120D, and this hole is filled with the porous body paste used to form the porous body 70D. When this multilayer body is fired, compared to the porous body paste used to form the porous body 70D that fills the hole, the multilayer body composed of green sheets surrounding the porous body paste (portion corresponding to the peripheral wall 111D) contracts to a greater extent (in particular, in directions along the plane). Therefore, the porous body paste in the hole is compressed by the multilayer body composed of the green sheets surrounding the porous body paste. Therefore, compared to, for example, when the porous body includes only the end portion and the tapered portion (when the lower end face of the tapered portion is exposed at the opening 12Dc) or when the porous body has a truncated conical shape that is tapered to widen in the direction from the gas outlet 12Db (first surface SD1) toward the opening 12Dc (second surface SD2), the porous body 70D of the present embodiment is less likely to be displaced and more strongly adheres to the plate-shaped member 11D (peripheral wall 111D) disposed therearound, as described above.

In addition, since the porous body 70D of the present embodiment includes the end portion 71D, the tapered portion 73D, and the column-shaped portion 74D, the volume of the porous body 70D can be minimized compared to a porous body in which the angle θ in FIG. 9 is 90°. In the retention substrate 10D including the porous body 70D of the present embodiment, the ratio of the ceramic portion (alumina) in the plate-shaped member 11D can be relatively increased, and high strength can be maintained.

### Other Embodiments

The present invention is not limited to the embodiments described above and illustrated in the drawings, and embodiments described below, for example, are also included in the technical scope of the present invention.
(1) The upper end face of the porous body exposed at the gas outlet may have a shape other than a circular shape (e.g., a polygonal shape) as long as the object of the present invention is achieved.
(2) The upper end face of the porous body may be disposed below the first surface as long as the object of the present invention is achieved.
(3) The number of support portions formed on the porous body at a side adjacent to the second surface and supported on the bottom portion (bottom surface) of the horizontal channel section may be one or two or more.
(4) The gas channel for allowing the inert gas to pass therethrough may not necessarily be formed in the base member, and may be formed only in the retention substrate.
(5) The method for manufacturing the retention device according to the above-described embodiment is an example, and the retention device may be manufactured by other methods as long as the object of the present invention is achieved.

### REFERENCE SIGNS LIST

100 retention device
10 retention substrate
11 plate-shaped member
12 substrate gas channel (gas channel)
12b gas outlet
120 first vertical channel section (vertical channel section)
130 horizontal channel section
140 second vertical channel section
70 porous body
70a upper end face
70b lower end face
V space
S1 first surface
S2 second surface
W wafer (object)

What is claimed is:

1. A retention device comprising a retention substrate including: a plate-shaped member having a first surface and a second surface and containing a ceramic material as a main component, the first surface for retaining an object, the second surface disposed opposite to the first surface; a gas channel formed in the plate-shaped member; and a gas-permeable porous body filling part of the gas channel and containing a ceramic material as a main component,
wherein the gas channel includes a vertical channel section and a horizontal channel section, the vertical channel section having a gas outlet that opens in the first surface and extending from the gas outlet toward the second surface, the horizontal channel section connected to the vertical channel section and extending parallel to the first surface, and
wherein the porous body fills the vertical channel section such that a space is formed on a side of the porous body adjacent to the second surface and inside the horizontal channel section.

2. The retention device according to claim 1, wherein the porous body has a convex end face adjacent to the second surface and facing the space, the convex end face bulging toward the second surface.

3. The retention device according to claim 1, wherein the porous body has a concave end face adjacent to the second surface and facing the space, the concave end face being recessed toward the first surface.

4. The retention device according to claim 1, wherein the horizontal channel section includes a bottom surface facing the porous body, and
wherein the porous body includes a body portion filling the vertical channel section and a support portion extending from the body portion to the bottom surface such that the space is formed on a side of the body portion adjacent to the second surface and such that the body portion is supported above the bottom surface.

5. The retention device according to claim 1, wherein the porous body includes a wide portion that is disposed closer to the second surface than the gas outlet and that is larger than the gas outlet in a radial direction.

6. The retention device according to claim 1, wherein the space is located at one end of the horizontal channel section.

7. The retention device according to claim 1, wherein the porous body has an upper end face that is disposed closer to the second surface than the first surface.

8. The retention device according to claim 1, wherein
the horizontal channel section includes a bottom surface facing the porous body and an upper surface facing the bottom surface, and
the porous body has a side wall that is in contact with an inner surface of the vertical channel section and extends to the upper surface of the horizontal channel section.
